(19) United States
(12) Patent Application Publication
(10) Pub. No.: US 2024/0377459 A1
(43) Pub. Date: Nov. 14, 2024

(54) Method and Device for Determining Grade of Energy Storage Station Based on Index Evaluation System

(71) Applicant: INNER MONGOLIA POWER (GROUP) CO., LTD INNER MONGOLIA POWER RESEARCH INSTITUTE, Huhhot (CN)

(72) Inventors: Zaixin YANG, Huhhot (CN); Baiqing YIN, Huhhot (CN); Minfu A., Huhhot (CN); Yunmin WANG, Huhhot (CN); Yuzhu WU, Huhhot (CN); Jun TAO, Huhhot (CN); Yuqiang WANG, Huhhot (CN); Tao HAN, Huhhot (CN); Feng LIU, Huhhot (CN)

(73) Assignee: INNER MONGOLIA POWER (GROUP) CO., LTD INNER MONGOLIA POWER RESEARCH INSTITUTE, Huhhot (CN)

(21) Appl. No.: 18/403,734

(22) Filed: Jan. 4, 2024

(30) Foreign Application Priority Data
May 9, 2023 (CN) 202310527757.5

(51) Int. Cl. G01R 31/367; G01R 31/36; G01R 31/382

(52) U.S. Cl. CPC G01R 31/367; G01R 31/3646; G01R 31/3648; G01R 31/3647; G01R 31/382

(57) ABSTRACT

Provided are method and device for determining grade of energy storage station based on index evaluation system, including for indicator score of at least one of evaluation indicators for each energy storage station, utilizing objective weighting method based on the indicator score of each evaluation indicator of energy storage station to determine objective weight of each evaluation indicator of the energy storage station; utilizing mixed decision-making model based on the indicator score of each evaluation indicator of energy storage station to determine subjective weight of each evaluation indicator of energy storage station; determining comprehensive weight of each evaluation indicator of the energy storage station based on the objective weight and the subjective weight of each evaluation indicator of energy storage station; and utilizing, based on the comprehensive weight of each evaluation indicator of each energy storage station, the TOPSIS method to determine evaluation grade of each energy storage station.

### CROSS-REFERENCE TO RELATED APPLICATION

The present disclosure claims the priority to the Chinese patent application with the filing No. 202310527757.5 filed with the Chinese Patent Office on May 9, 2023, and entitled “Method and Device for Determining Grade of Energy Storage Station Based on Index Evaluation System”, the contents of which are incorporated herein by reference in entirety.

### TECHNICAL FIELD

The present disclosure relates to the field of energy storage station management, and specifically to a method and a device for determining the grade of an energy storage station based on an index evaluation system

### BACKGROUND ART

With the development of science and technology and the increasing demand for electric power, energy storage stations are becoming increasingly important in supporting the construction of a new power system dominated by new energy. Energy storage stations play a significant role in actively supporting the power system in areas such as ancillary frequency regulation, power fluctuation suppression, and voltage control. Additionally, the participation of energy storage stations in the new power system can facilitate the power generation and absorption of new energy.

Energy storage stations, as an indispensable part of the power system, require a grade assessment to ensure the normal operation of the power system. This provides information about the status of the energy storage station based on the results of the evaluation grade obtained after the evaluation, thus enabling subsequent control of both the energy storage station and the power system according to the state of the energy storage station.

In prior art, when assessing the grade of energy storage stations, the evaluation grade of the energy storage station is typically determined by relevant personnel based on historical experience using operational data from each energy storage station. However, when determining the evaluation grade of energy storage stations through the above-mentioned method, there is a potential risk of errors in the evaluation grade determined due to insufficient experience of relevant personnel, thereby reducing the accuracy of the obtained evaluation grade. Additionally, since it is necessary to determine the evaluation grade for each energy storage station, the involvement of relevant personnel in every assessment process can significantly increase the human labor costs required for determining the evaluation grade of energy storage stations.

### SUMMARY

In view of the above, the objective of the present disclosure is to provide a method and a device for determining the grade of an energy storage station based on an index evaluation system. Therefore, the accuracy of the obtained evaluation grade of the energy storage station is enhanced, concurrently reducing the human labor costs required for determining the evaluation grade of the energy storage station.

In the first aspect, the embodiments of the present disclosure provide a method for determining the grade of an energy storage station based on an index evaluation system, wherein the method comprises
obtaining, for at least one energy storage station, an indicator score of at least one evaluation indicator of the energy storage station;
utilizing an objective weighting method based on the indicator score of each evaluation indicator of the energy storage station to determine an objective weight of each evaluation indicator of the energy storage station;
utilizing a DEMATEL-ANP mixed decision-making model based on the indicator score of each evaluation indicator of the energy storage station to determine a subjective weight of each evaluation indicator of the energy storage station;
determining a comprehensive weight of each evaluation indicator of the energy storage station based on the objective weight and the subjective weight of each evaluation indicator of the energy storage station; and
utilizing, based on the comprehensive weight of each evaluation indicator of each energy storage station, the TOPSIS method to determine an evaluation grade of each energy storage station.

Optionally, the at least one evaluation indicator comprises
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

Optionally, the step of obtaining an indicator score of at least one evaluation indicator of the energy storage station comprises
determining an indicator score of the charge and discharge capacity based on an actual dischargeable power of the energy storage station, a rated power of the energy storage station, an actual dischargeable volume of the energy storage station, and a rated energy of the energy storage station;
determining an indicator score of the energy efficiency level based on an on-grid electricity of the energy storage station, an off-grid electricity of the energy storage station, a total charging amount of the energy storage station, a total discharging amount of the energy storage station, and a self-consumption electricity of the energy storage station;
determining an indicator score of the failure frequency based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station;
determining an indicator score of the power control based on an active-power change rate of the energy storage station and an up/down active-power adjustment speed of the energy storage station;
determining an indicator score of the peak-shaving and valley-filling capability of a system based on a maximum available charging power of the energy storage station, a maximum available discharging power of the energy storage station, a response lag time of the energy storage station, and a steady-state control deviation of the energy storage station;
determining an indicator score of the system frequency regulation based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station;
determining an indicator score of the reactive power support based on an automatic-voltage-control adjustment speed of the energy storage station, an automatic-voltage-control adjustment precision of the energy storage station, and an automatic-voltage-control response time of the energy storage station;
determining an indicator score of the response success rate based on actual execution success times of an automatic-voltage-control and automatic-power-generation-control instructions from a grid within the preset operation scheduling cycle of the energy storage station, and a total number of the automatic-voltage-control and automatic-power-generation-control instructions issued by the grid to the energy storage station;
determining an indicator score of the equivalent utilization coefficient based on a number of operating hours of the energy storage station and a number of statistical hours within an evaluation period of the energy storage station;
determining an indicator score of the outage coefficient based on an unplanned outage coefficient of the energy storage station, a planned outage coefficient of the energy storage station, a number of unplanned outage hours of the energy storage station, a number of planned outage hours of the energy storage station, and a number of statistical hours within the evaluation period of the energy storage station;
determining an indicator score of the availability coefficient based on an available time of the energy storage station within the evaluation period and a number of statistical hours within the evaluation period of the energy storage station;
determining an indicator score of the frequency proactive support capability based on a steady-state frequency deviation of the energy storage station, a maximum frequency change rate of the energy storage station, a maximum frequency deviation of the energy storage station, an unbalanced power of the energy storage station, an equivalent damping of the system where the energy storage station is located, a primary frequency control intensity of the system where the energy storage station is located, and an equivalent inertia of the system where the energy storage station is located;
determining an indicator score of the voltage proactive support capability based on a matrix of reactive power flowing from regional power grid boundary to internal regions for which the energy storage station participates in regulation, a matrix of voltage at regional power grid boundary nodes for which the energy storage station participates in regulation, and a matrix of parameters at regional power grid boundary nodes for which the energy storage station participates in regulation;
determining an indicator score of the transient stability support capability based on an additional active output of the energy storage station to the system during transient processes, an additional reactive output of the energy storage station to the system during transient processes, a frequency deviation at the grid connection point of the energy storage station, and a natural logarithm voltage deviation at the grid connection point of the energy storage station;
determining an indicator score of the cost per unit of electricity based on a total cost of the energy storage station within the evaluation period and a total discharging amount of the energy storage station within the evaluation period;
determining an indicator score of the net present value based on the revenue of the energy storage station within the evaluation period, a cost and a discount rate of the energy storage station within the evaluation period;
determining an indicator score of the return on investment based on an annual-interest pre-tax profit of the energy storage station in a normal year and a total investment of the energy storage station;
determining an indicator score of the carbon emission reduction based on a carbon emission coefficient and a released renewable energy amount of the energy storage station;
determining an indicator score of the effective emission reduction rate based on a clean energy generation amount of the energy storage station within the evaluation period and a total discharging amount of the energy storage station within the evaluation period; and
determining an indicator score of the clean energy absorption rate based on a clean energy generation amount of the energy storage station within the evaluation period and a maximum clean energy generation amount of the energy storage station.

Optionally, the objective weighting method is the CRITIC weighting method.

Optionally, the step of determining a comprehensive weight of each evaluation indicator of the energy storage station based on the objective weight and the subjective weight of each evaluation indicator of the energy storage station comprises
establishing an objective function based on the minimum discrimination information principle for determining the comprehensive weight; and
utilizing the objective function to determine a comprehensive weight of each evaluation indicator of the energy storage station based on the objective weight and the subjective weight of each evaluation indicator of the energy storage station.

In the second aspect, the embodiments of the present disclosure provide a device for determining the grade of an energy storage station based on an index evaluation system, wherein the device comprises
an indicator score acquisition module, configured for obtaining, for at least one energy storage station, an indicator score of at least one evaluation indicator of the energy storage station;
an objective weight determination module, configured for utilizing an objective weighting method based on the indicator score of each evaluation indicator of the energy storage station to determine an objective weight of each evaluation indicator of the energy storage station;
a subjective weight determination module, configured for utilizing a DEMATEL-ANP mixed decision-making model based on the indicator score of each evaluation indicator of the energy storage station to determine a subjective weight of each evaluation indicator of the energy storage station;
a comprehensive weight determination module, configured for determining a comprehensive weight of each evaluation indicator of the energy storage station based on the objective weight and the subjective weight of each evaluation indicator of the energy storage station; and
an evaluation grade determination module, configured for utilizing, based on the comprehensive weight of each evaluation indicator of each energy storage station, the TOPSIS method to determine an evaluation grade of each energy storage station.

Optionally, the at least one evaluation indicator comprises
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

Optionally, the indicator score acquisition module is configured for obtaining an indicator score of at least one evaluation indicator of the energy storage station, which is specifically configured for
determining an indicator score of the charge and discharge capacity based on an actual dischargeable power of the energy storage station, a rated power of the energy storage station, an actual dischargeable volume of the energy storage station, and a rated energy of the energy storage station;
determining an indicator score of the energy efficiency level based on an on-grid electricity of the energy storage station, an off-grid electricity of the energy storage station, a total charging amount of the energy storage station, a total discharging amount of the energy storage station, and a self-consumption electricity of the energy storage station;
determining an indicator score of the failure frequency based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station;
determining an indicator score of the power control based on an active-power change rate of the energy storage station and an up/down active-power adjustment speed of the energy storage station;
determining an indicator score of the peak-shaving and valley-filling capability of a system based on a maximum available charging power of the energy storage station, a maximum available discharging power of the energy storage station, a response lag time of the energy storage station, and a steady-state control deviation of the energy storage station;
determining an indicator score of the system frequency regulation based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station;
determining an indicator score of the reactive power support based on an automatic-voltage-control adjustment speed of the energy storage station, an automatic-voltage-control adjustment precision of the energy storage station, and an automatic-voltage-control response time of the energy storage station;
determining an indicator score of the response success rate based on actual execution success times of an automatic-voltage-control and automatic-power-generation-control instructions from a grid within the preset operation scheduling cycle of the energy storage station, and a total number of the automatic-voltage-control and automatic-power-generation-control instructions issued by the grid to the energy storage station;
determining an indicator score of the equivalent utilization coefficient based on a number of operating hours of the energy storage station and a number of statistical hours within an evaluation period of the energy storage station;
determining an indicator score of the outage coefficient based on an unplanned outage coefficient of the energy storage station, a planned outage coefficient of the energy storage station, a number of unplanned outage hours of the energy storage station, a number of planned outage hours of the energy storage station, and a number of statistical hours within the evaluation period of the energy storage station;
determining an indicator score of the availability coefficient based on an available time of the energy storage station within the evaluation period and a number of statistical hours within the evaluation period of the energy storage station;
determining an indicator score of the frequency proactive support capability based on a steady-state frequency deviation of the energy storage station, a maximum frequency change rate of the energy storage station, a maximum frequency deviation of the energy storage station, an unbalanced power of the energy storage station, an equivalent damping of the system where the energy storage station is located, a primary frequency control intensity of the system where the energy storage station is located, and an equivalent inertia of the system where the energy storage station is located;
determining an indicator score of the voltage proactive support capability based on a matrix of reactive power flowing from regional power grid boundary to internal regions for which the energy storage station participates in regulation, a matrix of voltage at regional power grid boundary nodes for which the energy storage station participates in regulation, and a matrix of parameters at regional power grid boundary nodes for which the energy storage station participates in regulation;
determining an indicator score of the transient stability support capability based on an additional active output of the energy storage station to the system during transient processes, an additional reactive output of the energy storage station to the system during transient processes, a frequency deviation at the grid connection point of the energy storage station, and a natural logarithm voltage deviation at the grid connection point of the energy storage station;
determining an indicator score of the cost per unit of electricity based on a total cost of the energy storage station within the evaluation period and a total discharging amount of the energy storage station within the evaluation period;
determining an indicator score of the net present value based on the revenue of the energy storage station within the evaluation period, a cost and a discount rate of the energy storage station within the evaluation period;
determining an indicator score of the return on investment based on an annual-interest pre-tax profit of the energy storage station in a normal year and a total investment of the energy storage station;
determining an indicator score of the carbon emission reduction based on a carbon emission coefficient and a released renewable energy amount of the energy storage station;
determining an indicator score of the effective emission reduction rate based on a clean energy generation amount of the energy storage station within the evaluation period and a total discharging amount of the energy storage station within the evaluation period; and
determining an indicator score of the clean energy absorption rate based on a clean energy generation amount of the energy storage station within the evaluation period and a maximum clean energy generation amount of the energy storage station.

Optionally, the objective weighting method is the CRITIC weighting method.

Optionally, the comprehensive weight determination module is configured for determining a comprehensive weight of each evaluation indicator of the energy storage station based on the objective weight and the subjective weight of each evaluation indicator of the energy storage station, which is specifically configured for
establishing an objective function based on the minimum discrimination information principle for determining the comprehensive weight; and
utilizing the objective function to determine a comprehensive weight of each evaluation indicator of the energy storage station based on the objective weight and the subjective weight of each evaluation indicator of the energy storage station.

The technical solution provided in the present disclosure includes but is not limited to the following advantageous effects.

By the above-mentioned step of obtaining, for at least one energy storage station, an indicator score of at least one evaluation indicator of the energy storage station, it is possible to obtain the indicator scores of the evaluation indicators of each energy storage station based on different assessment dimensions.

By the above-mentioned step of utilizing an objective weighting method based on the indicator score of each evaluation indicator of the energy storage station to determine an objective weight of each evaluation indicator of the energy storage station, and the step of utilizing a DEMATEL-ANP mixed decision-making model based on the indicator score of each evaluation indicator of the energy storage station to determine a subjective weight of each evaluation indicator of the energy storage station, it is possible to determine the objective weight and subjective weight of each evaluation indicator of the energy storage station.

By the above-mentioned step of determining a comprehensive weight of each evaluation indicator of the energy storage station based on the objective weight and the subjective weight of each evaluation indicator of the energy storage station and the step of utilizing, based on the comprehensive weight of each evaluation indicator of each energy storage station, the TOPSIS method to determine an evaluation grade of each energy storage station, it is possible to determine the evaluation grade of each energy storage station based on the objective weight and subjective weight of each evaluation indicator of the energy storage station.

By employing the aforementioned method, it is possible to determine the weight values of each evaluation indicator based on the indicator scores of each energy storage station across different evaluation indicators. Subsequently, using the weight values of each evaluation indicator of different energy storage stations, the evaluation grade of each energy storage station is determined. This avoids the involvement of relevant personnel and the interference of subjective experience, thus facilitating the determination of evaluation grades of the energy storage stations. At the same time, the accuracy of obtaining the evaluation grade of the energy storage station is enhanced, concurrently reducing the human labor costs required for determining the evaluation grade of the energy storage station.

To make the above objectives, features, and advantages of the present disclosure more evident and comprehensible, the following preferred embodiments are described in detail with the drawings.

### BRIEF DESCRIPTION OF DRAWINGS

To more clearly illustrate the technical solutions of the embodiments of the present disclosure, the following will briefly introduce the drawings used in the embodiments. It should be understood that the following drawings only show some embodiments of the present disclosure, and therefore they should not be regarded as a limitation on the scope. Those ordinary skilled in the art can also obtain other related drawings based on these drawings without inventive effort.

FIG. 1 illustrates a flowchart of a method for determining the grade of an energy storage station based on an index evaluation system provided in one embodiment of the present disclosure;

FIG. 2 illustrates a flowchart of the method for determining a comprehensive weight provided in one embodiment of the present disclosure; and

FIG. 3 illustrates a schematic structural diagram of a device for determining the grade of an energy storage station based on an index evaluation system provided in another embodiment of the present disclosure.

### DETAILED DESCRIPTION OF EMBODIMENTS

In order to make the objective, technical solution, and advantages of the present disclosure clearer, the following will provide a clear and complete description of the technical solution in the embodiments of the present disclosure, in conjunction with the drawings in the embodiments of the present disclosure. Obviously, the described embodiments are only a part of the embodiments of the present disclosure, rather than all embodiments. The components of embodiments of the present disclosure which are generally described and illustrated in the drawings herein can be arranged and designed in a variety of different configurations. Accordingly, the following detailed description of the embodiments of the present disclosure provided in the drawings is not intended to limit the scope of the claimed disclosure but merely represents selected embodiments of the present disclosure. Based on the embodiments in the present disclosure, all other embodiments obtained by those skilled in the art without making inventive efforts are within the scope of protection of the present disclosure.

### Embodiment 1

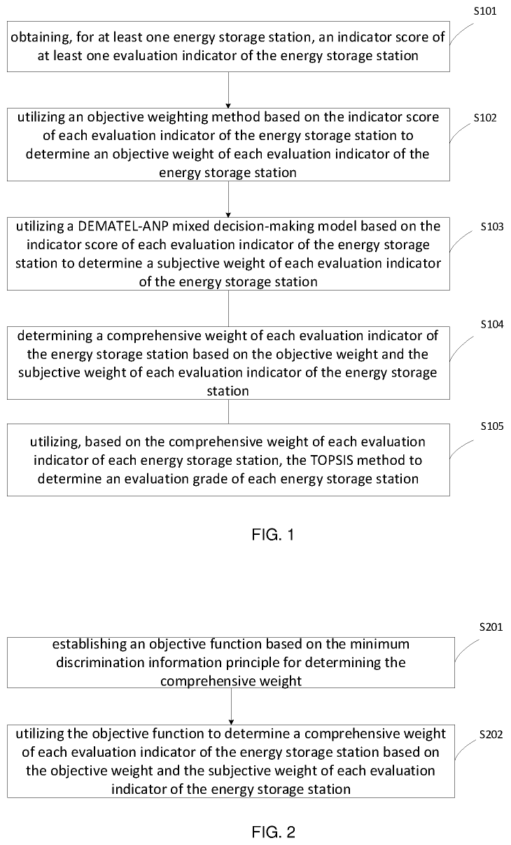

For the objective of facilitating an understanding of the present disclosure, one embodiment of the present disclosure is described in detail below in conjunction with the contents of the description of the flowchart of a method for determining the grade of an energy storage station based on an index evaluation system provided in one embodiment of the present disclosure illustrated in FIG. 1.

Referring to FIG. 1, FIG. 1 illustrates a flowchart of a method for determining the grade of an energy storage station based on an index evaluation system provided in one embodiment of the present disclosure, wherein the method includes the following steps S101 to S105.

S101: obtaining, for at least one energy storage station, an indicator score of at least one evaluation indicator of the energy storage station.

Specifically, each energy storage station has the same at least one evaluation indicator, and these evaluation indicators are included in a multi-scenario and multi-dimensional indicator evaluation system of the energy storage station, which is configured based on the station status and parameters of the energy storage station across multiple scenarios and dimensions.

The multi-scenario and multi-dimensional indicator evaluation system of the energy storage station divides the evaluation indicators into two levels. The first level includes a performance indicator, an application scenario indicator, an operational reliability indicator, a proactive support capability indicator, an economic indicator, and an environmental protection indicator. Each indicator in the first level has its own second-level indicator.

When the quantity of at least one energy storage station is n, and each energy storage station includes m evaluation indicators, for the j-th evaluation indicator of the i-th energy storage station, where n, m, i, and j are all non-zero natural numbers, with 1≤i≤n and 1≤j≤m, the subsequent steps S102 to S105 are performed.

S102: utilizing an objective weighting method based on the indicator score of each evaluation indicator of the energy storage station to determine an objective weight of each evaluation indicator of the energy storage station.

Specifically, the step of utilizing an objective weighting method based on the indicator score of each evaluation indicator of the energy storage station to determine an objective weight of each evaluation indicator of the energy storage station includes
standardizing the j-th evaluation indicator of the i-th energy storage station. Each evaluation indicator is categorized as a positive indicator or a negative indicator based on the positivity or negativity of its indicator score. When the indicator score of an evaluation indicator is positive, the evaluation indicator is determined to be a positive indicator; when the indicator score of the evaluation indicator is negative, the evaluation indicator is determined to be a negative indicator.

When the j-th evaluation indicator of the i-th energy storage station is a positive indicator, its indicator score xᵢⱼ is determined using the following expression:

$${x}_{i j} = \frac{{x}_{ij}^{′} - min \{ {x}_{ij}^{′} \}}{max \{ {x}_{ij}^{′} \} - min \{ {x}_{ij}^{′} \}} .$$

When the j-th evaluation indicator of the i-th energy storage station is a negative indicator, its indicator score xᵢⱼ is determined using the following expression:

$${x}_{i j} = \frac{max \{ {x}_{ij}^{′} \} - {x}_{ij}^{′}}{max \{ {x}_{ij}^{′} \} - min \{ {x}_{ij}^{′} \}} ,$$

where x′ᵢⱼ is the indicator score of the j-th evaluation indicator for the i-th energy storage station, min{x′ᵢⱼ} is the minimum standard value for the indicator score of the j-th evaluation indicator for the i-th energy storage station, and max{x′ᵢⱼ} is the maximum standard value for the indicator score of the j-th evaluation indicator for the i-th energy storage station.

The standardized indicator evaluation matrix X is determined based on the indicator scores for each evaluation indicator included in each energy storage station:

$$X = [ \begin{matrix}{x}_{11} & {x}_{12} & … & {x}_{1 m} \\ {x}_{21} & {x}_{22} & … & {x}_{2 m} \\ … & … & … & … \\ {x}_{n 1} & {x}_{n 2} & … & {x}_{n m}\end{matrix} ] .$$

The coefficient of variation vⱼ and correlation coefficient rᵢⱼ is calculated based on the indicator evaluation matrix X:

$$\begin{matrix}{v}_{j} = \frac{{s}_{j}}{\overline{{x}_{j}}} , \\ {r}_{i j} = \frac{cov ( {X}_{i} , {X}_{j} )}{{s}_{i} {s}_{j}} ,\end{matrix}$$

where sⱼ is the standard deviation of the j-th evaluation indicator in the standardized evaluation matrix X, sᵢ is the standard deviation of the i-th evaluation indicator in the standardized evaluation matrix X, x̅ⱼ̅ is the mean of the j-th evaluation indicator, and cov(Xᵢ, Xⱼ) is the covariance between the i-th evaluation indicator and the j-th evaluation indicator of the standardized evaluation matrix X.

The information content cⱼ of the evaluation indicators is determined based on the coefficient of variation and correlation coefficient. The information content of evaluation indicators includes the contrast intensity and conflict intensity between indicators:

$${c}_{j} = {v}_{j} {\sum }_{i = 1}^{m} ( 1 - {r}_{ij} ) ,$$

where j=1, 2, . . . , m.

The objective weight wⱼ^{A} of the j-th evaluation indicator is determined based on the information content of the evaluation indicators cⱼ:

$${w}_{j}^{A} = \frac{{c}_{j}}{{\sum }_{m} {c}_{j}} ;$$

where the greater the information content cⱼ of the evaluation indicator is, the more information the evaluation indicator includes, indicating stronger relative importance.

S103: utilizing a DEMATEL-ANP mixed decision-making model based on the indicator score of each evaluation indicator of the energy storage station to determine a subjective weight of each evaluation indicator of the energy storage station.

Specifically, the step of utilizing a DEMATEL-ANP mixed decision-making model based on the indicator score of each evaluation indicator of the energy storage station to determine a subjective weight of each evaluation indicator of the energy storage station includes
constructing a direct influence matrix based on the interrelationships of the j-th evaluation indicator of the i-th energy storage station, wherein i and j are considered as two elements in the mixed decision-making model, thus resulting in the direct influence matrix O:

$$O = {[ {o}_{ij} ]}_{mm} ,$$

where oᵢⱼ represents the influence of element i on element j, oᵢⱼ=0, 1, 2, 3, or 4, and m is the number of evaluation indicators included in each energy storage station.

The normalized matrix D is determined based on the direct influence matrix O:

$$D = \frac{O}{max \{ max {\sum }_{j = 1}^{m} {o}_{ij} , max {\sum }_{i = 1}^{m} {o}_{i j} \}} .$$

The comprehensive influence relationship matrix T is determined based on the normalized matrix D:

$$T = D \times {( I - D )}^{- 1} .$$

The column elements of the comprehensive influence relationship matrix T are normalized to obtain the weighted hypermatrix W^{t}.

The limit hypermatrix W_{DA} is determined and provided based on the weighted hypermatrix W^{t}:

$${W}_{D A} = {lim}_{t \to ∞} {W}^{t} ,$$

where, if the limit value converges and is unique, and at the same time, the column values of W_{DA} are the same and the sum of the columns is 1, then the subjective weight wⱼ^{S} of the j-th evaluation indicator is:

$${w}_{j}^{S} = {W}_{D A} .$$

S104: determining a comprehensive weight of each evaluation indicator of the energy storage station based on the objective weight and the subjective weight of each evaluation indicator of the energy storage station.

Specifically, the step of determining a comprehensive weight of each evaluation indicator of the energy storage station based on the objective weight and the subjective weight of each evaluation indicator of the energy storage station includes
establishing an objective function based on the minimum discrimination information principle for determining the comprehensive weight; and
utilizing the objective function to determine a comprehensive weight wⱼ of the j-th evaluation indicator of the energy storage station based on the objective weight and the subjective weight of each evaluation indicator of the energy storage station.

S105: utilizing, based on the comprehensive weight of each evaluation indicator of each energy storage station, the TOPSIS method to determine an evaluation grade of each energy storage station.

Specifically, the step of utilizing, based on the comprehensive weight of each evaluation indicator of each energy storage station, the TOPSIS method to determine an evaluation grade of each energy storage station includes
determining, based on the comprehensive weight wⱼ of each evaluation indicator of each energy storage station and the standardized indicator evaluation matrix X, the weighted evaluation matrix Z of the energy storage stations:

$$Z = [ \begin{matrix}{x}_{11} & {x}_{12} & … & {x}_{1 m} \\ {x}_{21} & {x}_{22} & … & {x}_{2 m} \\ … & … & … & … \\ {x}_{n 1} & {x}_{n 2} & … & {x}_{n m}\end{matrix} ] [ \begin{matrix}{w}_{1} & 0 & 0 & 0 \\ 0 & {w}_{2} & 0 & 0 \\ 0 & 0 & … & 0 \\ 0 & 0 & & {w}_{m}\end{matrix} ] = [ \begin{matrix}{z}_{11} & {z}_{12} & … & {z}_{1 m} \\ {z}_{21} & {z}_{22} & … & {z}_{2 m} \\ … & … & … & … \\ {z}_{n 1} & {z}_{n 2} & … & {z}_{n m}\end{matrix} ] ,$$

where 1≤j≤m, j is a natural number, n is the number of energy storage stations, and m is the number of evaluation indicators.

The positive ideal solution Zⱼ⁺ and negative ideal solution Zⱼ⁻ are calculated for the j-th evaluation indicator of the i-th energy storage station:

$$\{ \begin{matrix}{Z}_{j}^{+} = {max}_{1 \leq i \leq n} \{ {z}_{i j} \} , j = 1 , 2 , … , m \\ {Z}_{j}^{-} = {min}_{1 \leq i \leq n} \{ {z}_{i j} \} , j = 1 , 2 , … , m\end{matrix} ,$$

where zᵢⱼ represents the element value in the i-th row and j-th column of the weighted evaluation matrix Z.

Based on the positive ideal solution Zⱼ⁺ and negative ideal solution Zⱼ⁻ of the j-th evaluation indicator of the i-th energy storage station, the positive relative distance Z_{di}⁺ and negative relative distance Z_{di}⁻ are determined for the j-th evaluation indicator of the i-th energy storage station:

$$\begin{matrix}{Z}_{d i}^{+} = \sqrt{{\sum }_{j = 1}^{m} {( {Z}_{j}^{+} - {z}_{i j} )}^{2}} , i = 1 , 2 , … , n ; \\ {Z}_{d i}^{-} = \sqrt{{\sum }_{j = 1}^{m} {( {Z}_{j}^{-} - {z}_{i j} )}^{2}} , i = 1 , 2 , … , n .\end{matrix}$$

Based on the positive relative distance Z_{di}⁺ and negative relative distance Z_{di}⁻ of the j-th evaluation indicator of the i-th energy storage station, the proximity degree Hᵢ of the i-th energy storage station is determined:

$${H}_{i} = \frac{{Z}_{d i}^{-}}{{Z}_{d i}^{-} + {Z}_{d i}^{+}} , i = 1 , 2 , … , n .$$

According to the order of the proximity degree values from large to small, n energy storage stations are sorted. The larger Hᵢ of the energy storage station is, the closer the energy storage station is to the positive ideal solution, the better the comprehensive evaluation result of the energy storage station is, and the higher the evaluation grade of the energy storage station is.

For each energy storage station, based on the proximity degree value of the energy storage station, an evaluation grade having a mapping relationship with the proximity degree value of the energy storage station is determined, from a preset table of evaluation grades, to be the evaluation grade of the energy storage station. The proximity degree value of the energy storage station is positively correlated with the evaluation grade of the energy storage station.

In one feasible embodiment, the at least one evaluation indicator includes
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

In the multi-scenario and multi-dimensional indicator evaluation system of the energy storage station, each indicator in the first level includes its own second-level indicators. The performance indicators include a charge and discharge capacity, an energy efficiency level, and a failure frequency; the application scenario indicators include a power control, a peak-shaving and valley-filling capability of a system, a system frequency regulation, and a reactive power support; the operational reliability indicators include a response success rate, an equivalent utilization coefficient, an outage coefficient, and an availability coefficient; the active support capability indicators include a frequency proactive support capability, a voltage proactive support capability, and a transient stability support capability; the economic indicators include a cost per unit of electricity, a net present value, and a return on investment; and the environmental protection indicators include a carbon emission reduction, an effective emission reduction rate, and a clean energy absorption rate.

In one feasible embodiment, the step of obtaining an indicator score of at least one evaluation indicator of the energy storage station includes
determining an indicator score of the charge and discharge capacity based on an actual dischargeable power of the energy storage station, a rated power of the energy storage station, an actual dischargeable volume of the energy storage station, and a rated energy of the energy storage station.

Specifically, the indicator score α₁ of the charge and discharge capacity is determined based on the following expression:

$$\begin{matrix}{α}_{1} = {λ}_{1} {ω}_{1} + {λ}_{2} {ω}_{2} , \\ {ω}_{1} = \frac{{P}_{A D C}}{{P}_{N}} , \\ {ω}_{2} = \frac{{E}_{A D C}}{{E}_{N}} ,\end{matrix}$$

where λ₁ is the first predefined indicator weight, λ₂ is the second predefined indicator weight, ω₁ is the actual dischargeable power ratio of the energy storage station, ω₂ is the actual dischargeable capacity ratio of the energy storage station, P_{ADC} is the actual dischargeable power of the energy storage station, P_{N} is the rated power of the energy storage station, E_{ADC} is the actual dischargeable capacity of the energy storage station, and E_{N} is the rated energy of the energy storage station.

An indicator score of the energy efficiency level is determined based on an on-grid electricity of the energy storage station, an off-grid electricity of the energy storage station, a total charging amount of the energy storage station, a total discharging amount of the energy storage station, and a self-consumption electricity of the energy storage station.

Specifically, the energy efficiency level indicator α₂ is determined based on the following expression:

$$\begin{matrix}{α}_{2} = {λ}_{3} {ω}_{3} + {λ}_{4} {ω}_{4} + {λ}_{5} {ω}_{5} , \\ {ω}_{3} = \frac{{E}_{U P}}{{E}_{D O W N}} , \\ {ω}_{4} = \frac{{E}_{C}}{{E}_{D}} , \\ {ω}_{5} = \frac{{E}_{S E}}{{E}_{D O W N}} ,\end{matrix}$$

where λ₃ is the third predefined indicator weight, λ₄ is the fourth predefined indicator weight, λ₅ is the fifth predefined indicator weight, ω₃ is the overall efficiency of the energy storage station, ω₄ is the energy storage loss rate of the energy storage station, ω₅ is the self-consumption rate of the energy storage station, E_{UP} is the on-grid electricity of the energy storage station, E_{DOWN} is the off-grid electricity of the energy storage station, E_{C} is the total charging amount of the energy storage station, E_{D} is the total discharging amount of the energy storage station, and E_{SE} is the self-consumption electricity of the energy storage station.

An indicator score of the failure frequency is determined based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station.

Specifically, the failure frequency indicator α₃ is determined based on the following expression:

$$\begin{matrix}{α}_{3} = {λ}_{6} {ω}_{6} + {λ}_{7} {ω}_{7} , \\ {ω}_{6} = \frac{{N}_{B max} - {N}_{B}}{{N}_{B max}} , \\ {ω}_{7} = \frac{{N}_{P max} - {N}_{P}}{{N}_{P max}} ,\end{matrix}$$

where λ₆ is the sixth predefined indicator weight, λ₇ is the seventh predefined indicator weight, ω₆ is the relative failure frequency of the battery cluster in the energy storage station, N_{Bmax} is the relative failure frequency of the process control system in the energy storage station, N_{Bmax} is a battery-cluster failure frequency threshold of the energy storage station, N_{Pmax} is a process-control-system failure frequency threshold of the energy storage station, N_{B} is a battery-cluster stage-time failure frequency of the energy storage station, and N_{P} is a process-control-system stage-time failure frequency of the energy storage station.

An indicator score of the power control is determined based on an active-power change rate of the energy storage station and an up/down active-power adjustment speed of the energy storage station.

Specifically, the power control indicator α₄ is determined based on the following expression:

$${α}_{4} = {λ}_{8} {ω}_{8} + {λ}_{9} {ω}_{9} + {λ}_{10} {ω}_{10} ,$$

where λ₈ is the eighth predefined indicator weight, λ₉ is the ninth predefined indicator weight, λ₁₀ is the tenth predefined indicator weight, ω₈ is the 1-minute active-power change rate of the energy storage station, ω₉ is the 10-minute active-power change rate of the energy storage station, and ω₁₀ is the up/down active-power adjustment speed of the energy storage station.

An indicator score of the peak-shaving and valley-filling capability of the system is determined based on a maximum available charging power of the energy storage station, a maximum available discharging power of the energy storage station, a response lag time of the energy storage station, and a steady-state control deviation of the energy storage station.

Specifically, the indicator α₅ of peak-shaving and valley-filling capability is determined based on the following expression:

$${α}_{5} = {λ}_{11} {ω}_{11} + {λ}_{12} {ω}_{12} + {λ}_{13} {ω}_{13} + {λ}_{14} {ω}_{14} ,$$

where λ₁₁ is the eleventh predefined indicator weight, λ₁₂ is the twelfth predefined indicator weight, λ₁₃ is the thirteenth predefined indicator weight, λ₁₄ is the fourteenth predefined indicator weight, ω₁₁ is a maximum available charging power of the energy storage station, ω₁₂ is a maximum available discharging power of the energy storage station, ω₁₃ is a response lag time of the energy storage station, and ω₁₄ is a steady-state control deviation of the energy storage station.

An indicator score of the system frequency regulation is determined based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station.

Specifically, the system frequency regulation indicator α₆ is determined based on the following expression:

$${α}_{6} = {λ}_{15} {ω}_{15} + {λ}_{16} {ω}_{16} + {λ}_{17} {ω}_{17} + {λ}_{18} {ω}_{18} ,$$

where, λ₁₅ is the fifteenth predefined indicator weight, λ₁₆ is the sixteenth predefined indicator weight, λ₁₇ is the seventeenth predefined indicator weight, λ₁₈ is the eighteenth predefined indicator weight, ω₁₅ is a process-control-system protection-action time of frequency adaptability tests of the energy storage station, ω₁₆ is a process-control-system protection-action frequency of the frequency adaptability tests of the energy storage station, an automatic-power-generation-control adjustment speed of the energy storage station, ω₁₇ is an automatic-power-generation-control adjustment speed of the energy storage station, and ω₁₈ is an automatic-power-generation-control adjustment precision of the energy storage station.

An indicator score of the reactive power support is determined based on an automatic-voltage-control adjustment speed of the energy storage station, an automatic-voltage-control adjustment precision of the energy storage station, and an automatic-voltage-control response time of the energy storage station.

Specifically, the reactive power support indicator α₇ is determined based on the following expression:

$${α}_{7} = {λ}_{19} {ω}_{19} + {λ}_{20} {ω}_{20} + {λ}_{21} {ω}_{21} ,$$

where λ₁₉ is the nineteenth predefined indicator weight, λ₂₀ is the twentieth predefined indicator weight, λ₂₁ is the twenty-first predefined indicator weight, ω₁₉ is an automatic-voltage-control adjustment speed of the energy storage station, ω₂₀ is an automatic-voltage-control adjustment precision of the energy storage station, and ω₂₁ is an automatic-voltage-control response time of the energy storage station.

An indicator score of the response success rate is determined based on actual execution success times of an automatic-voltage-control and automatic-power-generation-control instructions from a grid within the preset operation scheduling cycle of the energy storage station, and a total number of the automatic-voltage-control and automatic-power-generation-control instructions issued by the grid to the energy storage station.

Specifically, the response success rate indicator α₈ is determined based on the following expression:

$${α}_{8} = \frac{{N}_{SUC}}{{N}_{T}} \times 100 \% ,$$

where N_{SUC} is actual execution success times of an automatic-voltage-control and automatic-power-generation-control instructions from a grid within the preset operation scheduling cycle of the energy storage station, and N_{T} is a total number of the automatic-voltage-control and automatic-power-generation-control instructions issued by the grid to the energy storage station.

An indicator score of the equivalent utilization coefficient is determined based on a number of operating hours of the energy storage station and a number of statistical hours within an evaluation period of the energy storage station.

Specifically, the equivalent utilization coefficient indicator α₉ is determined based on the following expression:

$${α}_{9} = \frac{U T H}{P H} \times 100 \% ,$$

where UTH is the number of the operating hours of the energy storage station, and PH is the number of the statistical hours within an evaluation period of the energy storage station.

An indicator score of the outage coefficient is determined based on an unplanned outage coefficient of the energy storage station, a planned outage coefficient of the energy storage station, a number of unplanned outage hours of the energy storage station, a number of planned outage hours of the energy storage station, and a number of statistical hours within the evaluation period of the energy storage station.

Specifically, the outage coefficient indicator α₁₀ is determined based on the following expression:

$${α}_{10} = {λ}_{22} {ω}_{22} + {λ}_{23} {ω}_{23} ,$$

$${ω}_{22} = \frac{U O H}{P H} \times 100 \% ,$$

$${ω}_{23} = \frac{P O H}{P H} \times 100 \% ,$$

where λ₂₂ is the twenty-second predefined indicator weight, λ₂₃ is the twenty-third predefined indicator weight, ω₂₂ is an unplanned outage coefficient of the energy storage station, ω₂₃ is a planned outage coefficient of the energy storage station, UOH is a number of unplanned outage hours of the energy storage station, POH is a number of planned outage hours of the energy storage station, and PH is a number of statistical hours within the evaluation period.

An indicator score of the availability coefficient is determined based on an available time of the energy storage station within the evaluation period and a number of statistical hours within the evaluation period of the energy storage station.

Specifically, the availability coefficient indicator α₁₁ is determined based on the following expression:

$${α}_{11} = \frac{A H}{P H} \times 100 \% ,$$

where AH is the available time of the energy storage station within the evaluation period and PH is the number of statistical hours within the evaluation period.

An indicator score of the frequency proactive support capability is determined based on a steady-state frequency deviation of the energy storage station, a maximum frequency change rate of the energy storage station, a maximum frequency deviation of the energy storage station, an unbalanced power of the energy storage station, an equivalent damping of the system where the energy storage station is located, a primary frequency control intensity of the system where the energy storage station is located, and an equivalent inertia of the system where the energy storage station is located.

Specifically, the frequency proactive support capability indicator ω₁₂ is determined based on the following expression:

$${α}_{12} = {λ}_{24} {ω}_{24} + {λ}_{25} {ω}_{25} + {λ}_{26} {ω}_{26} ,$$

$${ω}_{24} = \frac{Δ P}{\overline{d} + {α}_{g}} ,$$

$${ω}_{25} = \frac{Δ P}{\overline{M}} ,$$

$${ω}_{26} = \frac{\vert Δ P \vert}{\overline{d} + {α}_{g}} ( 1 + \sqrt{\frac{{τα}_{g}}{\overline{M}}} {e}^{- \frac{η}{{ω}_{d}} ( ϕ + \frac{π}{2} )} ) ,$$

$${ω}_{d} {=}^{Δ} \sqrt{( d + {α}_{g} ) {τ}^{- 1} {\overline{M}}^{- 1} - \frac{1}{4} {( {τ}^{- 1} + \overline{d} {\overline{M}}^{- 1} )}^{2}} ,$$

$$η {=}^{Δ} \frac{1}{2} ( {τ}^{- 1} + \overline{d} {\overline{M}}^{- 1} ) ,$$

where λ₂₄ is the twenty-fourth predefined indicator weight, λ₂₅ is the twenty-fifth predefined indicator weight, λ₂₆ is the twenty-sixth predefined indicator weight, ω₂₄ is a steady-state frequency deviation of the energy storage station, ω₂₅ is a maximum frequency change rate of the energy storage station, ω₂₆ is a maximum frequency deviation of the energy storage station, ΔP is an unbalanced power of the energy storage station, d̅ is an equivalent damping of the energy storage system where the energy storage station is located, α_{g} is a primary frequency control intensity of the system where the energy storage station is located, M̅ is an equivalent inertia of the system where the energy storage station is located, τ is the time constant, e is the natural constant, ϕ is the phase angle of the system where the energy storage station is located, and η±jω_{d} is the second-order pole of the system where the energy storage station is located, wherein j is the imaginary unit and has a different meaning from other instances of j herein.

An indicator score of the voltage proactive support capability is determined based on a matrix of reactive power flowing from regional power grid boundary to internal regions for which the energy storage station participates in regulation, a matrix of voltage at regional power grid boundary nodes for which the energy storage station participates in regulation, and a matrix of parameters at regional power grid boundary nodes for which the energy storage station participates in regulation.

Specifically, the voltage proactive support capability indicator α₁₃ is determined based on the following expression:

$${α}_{13} = ( {\tilde{Q}}_{B} - {\tilde{Q}}_{B , r e f} ) - {K}_{Q S} ( {U}_{B} - {U}_{B , ref} ) ,$$

where \tilde{Q}_{B} is a matrix of reactive power flowing from regional power grid boundary to internal regions for which the energy storage station participates in regulation, U_{B} is a matrix of voltage at regional power grid boundary nodes of the energy storage station, K_{QS} is a matrix of parameters at regional power grid boundary nodes for which the energy storage station participates in regulation, \tilde{Q}_{B,ref} is the reference value of the reactive power matrix, and U_{B,ref} is the reference value of the voltage matrix at the grid boundary nodes.

An indicator score of the transient stability support capability is determined based on an additional active output of the energy storage station to the system during transient processes, an additional reactive output of the energy storage station to the system during transient processes, a frequency deviation at the grid connection point of the energy storage station, and a natural logarithm voltage deviation at the grid connection point of the energy storage station.

Specifically, the transient stability support capability indicator α₁₄ is determined based on the following expression:

$${α}_{14} = \int [ ( Δ {P}_{i} \cdot 2 πΔ {f}_{i} ) d t + Δ {Q}_{i} d ( Δ ln {U}_{i} ) ] ,$$

where ΔPₜ is an additional active output of the energy storage station to the system during transient processes, ΔQᵢ is an additional reactive output of the energy storage station to the system during transient processes, Δfᵢ is a frequency deviation at the grid connection point of the energy storage station, and Δln Uᵢ is a natural logarithm voltage deviation at the grid connection point of the energy storage station.

An indicator score of the cost per unit of electricity is determined based on a total cost of the energy storage station within the evaluation period and a total discharging amount of the energy storage station within the evaluation period.

Specifically, the indicator of cost per unit of electricity α₁₅ is determined based on the following expression:

$${α}_{15} = \frac{C}{{E}_{D}} ,$$

where C is a total cost of the energy storage station within the evaluation period and E_{D} is a total discharging amount of the energy storage station within the evaluation period.

An indicator score of the net present value is determined based on the revenue of the energy storage station within the evaluation period, a cost, and a discount rate of the energy storage station within the evaluation period.

Specifically, the net present value indicator α₁₆ is determined based on the following expression:

$${α}_{16} = {\sum }_{t = 1}^{n} ( {S}_{t} - {C}_{t} ) {( 1 + γ )}^{- t} ,$$

where Sₜ is the revenue of the energy storage station within the evaluation period, Cₜ is a cost within the evaluation period, γ is a discount rate, and t is the evaluation period of the energy storage station.

An indicator score of the return on investment is determined based on an annual-interest pre-tax profit of the energy storage station in a normal year and a total investment of the energy storage station.

Specifically, the indicator of return on investment α₁₇ is determined based on the following expression:

$${α}_{17} = \frac{{P}_{r}}{TI} \times 100 \% ,$$

where Pᵣ is the annual-interest pre-tax profit in a normal year for the energy storage station, and TI is the total investment for the energy storage station.

An indicator score of the carbon emission reduction is determined based on a carbon emission coefficient and a released renewable energy amount of the energy storage station.

Specifically, the carbon emission reduction indicator α₁₈ is determined based on the following expression:

$${α}_{18} = {\sum }_{t = 1}^{n} {e}_{CO 2} {E}_{Dt} ,$$

where e_{CO2} is a carbon emission coefficient and E_{Dt} is a released renewable energy amount of the energy storage station, and n is the number of energy storage stations.

An indicator score of the effective emission reduction rate is determined based on a clean energy generation amount of the energy storage station within the evaluation period and a total discharging amount of the energy storage station within the evaluation period.

Specifically, the indicator α₁₉ of effective emission reduction rate is determined based on the following expression:

$${α}_{19} = \frac{\sum {E}_{C D}}{\sum {E}_{D}} \times 100 \% ,$$

where E_{CD} is a clean energy generation amount of the energy storage station within the evaluation period and E_{D} is a total discharging amount of the energy storage station within the evaluation period.

An indicator score of the clean energy absorption rate is determined based on a clean energy generation amount of the energy storage station within the evaluation period and a maximum clean energy generation amount of the energy storage station.

Specifically, the indicator α₂₀ of clean energy absorption rate is determined based on the following expression:

$${α}_{20} = \frac{{E}_{C D}}{{E}_{CD max}} ,$$

where E_{CD} is a clean energy generation amount of the energy storage station within the evaluation period and E_{CDmax} is a maximum clean energy generation amount of the energy storage station.

In one feasible embodiment, the objective weighting method is the CRITIC weighting method.

Specifically, the CRITIC weighting method is an objective weighting method based on the volatility of data.

In one feasible embodiment as shown in FIG. 2, FIG. 2 illustrates a flowchart of the method for determining a comprehensive weight provided in one embodiment of the present disclosure. The step of determining a comprehensive weight of each evaluation indicator of the energy storage station based on the objective weight and the subjective weight of each evaluation indicator of the energy storage station includes the following steps S201 to S202.

S201: establishing an objective function based on the minimum discrimination information principle for determining the comprehensive weight.

Specifically, when the quantity of at least one energy storage station is n, and each energy storage station includes m evaluation indicators, for the j-th evaluation indicator of the i-th energy storage station, where n, m, i, and j are all non-zero natural numbers, with 1≤i≤n and 1≤j≤m, the objective function is:

$$\{ \begin{matrix}min F ( w ) = {\sum }_{j = 1}^{m} ( {w}_{i} ln \frac{{w}_{i}}{{w}_{j}^{A}} + {w}_{i} ln \frac{{w}_{i}}{{w}_{j}^{S}} ) \\ \begin{matrix}{\sum }_{j = 1}^{m} {w}_{j} = 1 , {w}_{j} \geq 0 & j = 1 , 2 , … , m\end{matrix}\end{matrix} ,$$

where min F (w) is the minimum discriminant information function between subjective and objective weights, wᵢ is the independent variable of the objective function, wⱼ^{A} is the objective weight of the j-th evaluation indicator of the energy storage station, and wⱼ^{S} is the subjective weight of the j-th evaluation indicator of the energy storage station.

S202: utilizing the objective function to determine a comprehensive weight of each evaluation indicator of the energy storage station based on the objective weight and the subjective weight of each evaluation indicator of the energy storage station.

Specifically, for the j-th evaluation indicator of the energy storage station, the objective weight and subjective weight of the j-th evaluation indicator of the energy storage station are input into the objective function. The objective function is solved to obtain the comprehensive weight wⱼ of the j-th evaluation indicator of the energy storage station.

$${w}_{j} = \frac{\sqrt{{w}_{j}^{A} {w}_{j}^{S}}}{{Σ}_{j = 1}^{m} \sqrt{{w}_{j}^{A} {w}_{j}^{S}}} ;$$

where wⱼ is the comprehensive weight of the j-th evaluation indicator of the energy storage station, wⱼ^{A} is the objective weight of the j-th evaluation indicator of the energy storage station, wⱼ^{S} is the subjective weight of the j-th evaluation indicator of the energy storage station, and m is the number of evaluation indicators of the energy storage station.

### Embodiment 2

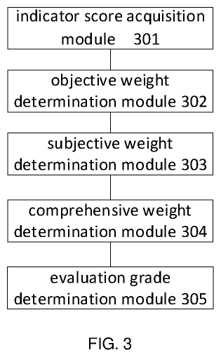

As shown in FIG. 3, FIG. 3 illustrates a schematic structural diagram of a device for determining the grade of an energy storage station based on an index evaluation system based on another embodiment of the present disclosure, wherein the device includes
an indicator score acquisition module 301, configured for obtaining, for at least one energy storage station, an indicator score of at least one evaluation indicator of the energy storage station;
an objective weight determination module 302, configured for utilizing an objective weighting method based on the indicator score of each evaluation indicator of the energy storage station to determine an objective weight of each evaluation indicator of the energy storage station;
a subjective weight determination module 303, configured for utilizing a DEMATEL-ANP mixed decision-making model based on the indicator score of each evaluation indicator of the energy storage station to determine a subjective weight of each evaluation indicator of the energy storage station;
a comprehensive weight determination module 304, configured for determining a comprehensive weight of each evaluation indicator of the energy storage station based on the objective weight and the subjective weight of each evaluation indicator of the energy storage station; and
an evaluation grade determination module 305, configured for utilizing, based on the comprehensive weight of each evaluation indicator of each energy storage station, the TOPSIS method to determine an evaluation grade of each energy storage station.

In one feasible embodiment, the at least one evaluation indicator includes
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

In one feasible embodiment, the indicator score acquisition module is configured for obtaining an indicator score of at least one evaluation indicator of the energy storage station, which is specifically configured for
determining an indicator score of the charge and discharge capacity based on an actual dischargeable power of the energy storage station, a rated power of the energy storage station, an actual dischargeable volume of the energy storage station, and a rated energy of the energy storage station;
determining an indicator score of the energy efficiency level based on an on-grid electricity of the energy storage station, an off-grid electricity of the energy storage station, a total charging amount of the energy storage station, a total discharging amount of the energy storage station, and a self-consumption electricity of the energy storage station;
determining an indicator score of the failure frequency based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station;
determining an indicator score of the power control based on an active-power change rate of the energy storage station and an up/down active-power adjustment speed of the energy storage station;
determining an indicator score of the peak-shaving and valley-filling capability of a system based on a maximum available charging power of the energy storage station, a maximum available discharging power of the energy storage station, a response lag time of the energy storage station, and a steady-state control deviation of the energy storage station;
determining an indicator score of the system frequency regulation based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station;
determining an indicator score of the reactive power support based on an automatic-voltage-control adjustment speed of the energy storage station, an automatic-voltage-control adjustment precision of the energy storage station, and an automatic-voltage-control response time of the energy storage station;
determining an indicator score of the response success rate based on actual execution success times of an automatic-voltage-control and automatic-power-generation-control instructions from a grid within the preset operation scheduling cycle of the energy storage station, and a total number of the automatic-voltage-control and automatic-power-generation-control instructions issued by the grid to the energy storage station;
determining an indicator score of the equivalent utilization coefficient based on a number of operating hours of the energy storage station and a number of statistical hours within an evaluation period of the energy storage station;
determining an indicator score of the outage coefficient based on an unplanned outage coefficient of the energy storage station, a planned outage coefficient of the energy storage station, a number of unplanned outage hours of the energy storage station, a number of planned outage hours of the energy storage station, and a number of statistical hours within the evaluation period of the energy storage station;
determining an indicator score of the availability coefficient based on an available time of the energy storage station within the evaluation period and a number of statistical hours within the evaluation period of the energy storage station;
determining an indicator score of the frequency proactive support capability based on a steady-state frequency deviation of the energy storage station, a maximum frequency change rate of the energy storage station, a maximum frequency deviation of the energy storage station, an unbalanced power of the energy storage station, an equivalent damping of the system where the energy storage station is located, a primary frequency control intensity of the system where the energy storage station is located, and an equivalent inertia of the system where the energy storage station is located;
determining an indicator score of the voltage proactive support capability based on a matrix of reactive power flowing from regional power grid boundary to internal regions for which the energy storage station participates in regulation, a matrix of voltage at regional power grid boundary nodes for which the energy storage station participates in regulation, and a matrix of parameters at regional power grid boundary nodes for which the energy storage station participates in regulation;
determining an indicator score of the transient stability support capability based on an additional active output of the energy storage station to the system during transient processes, an additional reactive output of the energy storage station to the system during transient processes, a frequency deviation at the grid connection point of the energy storage station, and a natural logarithm voltage deviation at the grid connection point of the energy storage station;
determining an indicator score of the cost per unit of electricity based on a total cost of the energy storage station within the evaluation period and a total discharging amount of the energy storage station within the evaluation period;
determining an indicator score of the net present value based on the revenue of the energy storage station within the evaluation period, a cost and a discount rate of the energy storage station within the evaluation period;
determining an indicator score of the return on investment based on an annual-interest pre-tax profit of the energy storage station in a normal year and a total investment of the energy storage station;
determining an indicator score of the carbon emission reduction based on a carbon emission coefficient and a released renewable energy amount of the energy storage station;
determining an indicator score of the effective emission reduction rate based on a clean energy generation amount of the energy storage station within the evaluation period and a total discharging amount of the energy storage station within the evaluation period; and
An indicator score of the clean energy absorption rate is determined based on a clean energy generation amount of the energy storage station within the evaluation period and a maximum clean energy generation amount of the energy storage station.

In one feasible embodiment, the objective weighting method is the CRITIC weighting method.

In one feasible embodiment, the comprehensive weight determination module is configured for determining a comprehensive weight of each evaluation indicator of the energy storage station based on the objective weight and the subjective weight of each evaluation indicator of the energy storage station, which is specifically configured for
establishing an objective function based on the minimum discrimination information principle for determining the comprehensive weight; and
utilizing the objective function to determine a comprehensive weight of each evaluation indicator of the energy storage station based on the objective weight and the subjective weight of each evaluation indicator of the energy storage station.

The device for determining the grade of an energy storage station based on an index evaluation system, as provided in the embodiment of the present disclosure, can be implemented as specific hardware on the device or as software or firmware installed on the device. The device provided by the embodiment of the present disclosure is implemented with the same principles and produces the same technical effects as the aforementioned method embodiment. For a brief description, where the embodiment part of the device is not mentioned, the corresponding contents of the aforementioned embodiment method can be referred to. It will be clear to those skilled in the field that, for the convenience and brevity of the description, the specific working processes of the systems, devices, and units described above can be referred to as the corresponding processes in the preceding method embodiments and will not be repeated here.

In the embodiments provided in the present disclosure, it should be understood that the systems, devices, and methods disclosed, can be implemented in other ways. The above-described embodiments of the device are merely schematic, for example, the division of the units described, which is only a logical functional division, can be divided in another way when actually implemented; also, for example, multiple units or components can be combined or can be integrated into another system, or some features can be ignored, or not implemented. On another point, the mutual coupling, direct coupling, or communication connection discussed herein can be an indirect coupling or communication connection through communication interfaces, devices, or units, which can be electrical, mechanical, or other forms.

The units illustrated as separate components may/may not be physically separated, and the components displayed as units may/may not be physical units, i.e., they can be located in one place or distributed to a plurality of network units. Some or all of these units can be selected according to actual needs to achieve the objective of the embodiment solution.

Further, each functional unit in the embodiments of the present disclosure can be integrated into a single processing unit, each unit can be physically present separately, or two or more units can be integrated into a single unit.

The functionality, when implemented as a software functional unit and sold or used as a stand-alone product, can be stored in a computer-readable storage medium. Based on this understanding, the technical solution of the present disclosure can essentially be embodied in the form of a software product, which contributes to or includes parts of the existing technology. The software product is stored in a storage medium and includes multiple instructions for causing a computer device (which can be a personal computer, server, network device, etc.) to execute all or some of the steps of the methods described in various embodiments of the present disclosure. The aforementioned storage media comprises various media that can store program code, such as various media that can store program code, such as USB flash drives, mobile hard drives, Read-Only Memory (ROM), Random Access Memory (RAM), disks, or CD-ROMs.

It should be noted that similar numerals and letters denote similar terms in the following drawings. Therefore, once an item is defined in one drawing, it does not need to be further discussed in subsequent drawings. In addition, the terms “first”, “second”, and “third” are only used to distinguish the descriptive and are not to be construed as indicating or implying relative importance.

Finally, it should be noted that the embodiments described above are specific implementations of the present disclosure used to illustrate the technical solutions of the present disclosure and are not intended to limit its scope. The scope of protection of the present disclosure is not limited to these embodiments, despite the detailed description provided in reference to the aforementioned embodiments. It should be understood by those of ordinary skill in the art that any person skilled in the art can still make modifications or easily envisage variations to the technical solutions described in the aforementioned embodiments within the technical scope disclosed by the present disclosure. Alternatively, some technical features can be equivalently substituted. These modifications, changes, or replacements do not take the essence of the corresponding technical solutions out of the essence and scope of the technical solutions of the embodiments of the present disclosure. All should be covered within the scope of protection of the present disclosure. Therefore, the scope of protection of the present disclosure should be determined by the scope of protection of the claims.

What is claimed is:

1. A method for determining a grade of an energy storage station based on an index evaluation system, wherein the method comprises
obtaining, for at least one energy storage station, an indicator score of at least one evaluation indicator of the energy storage station;
utilizing an objective weighting method based on an indicator score of each evaluation indicator of the energy storage station to determine an objective weight of each evaluation indicator of the energy storage station;
utilizing a DEMATEL-ANP mixed decision-making model based on the indicator score of each evaluation indicator of the energy storage station to determine a subjective weight of each evaluation indicator of the energy storage station;
determining a comprehensive weight of each evaluation indicator of the energy storage station based on the objective weight and the subjective weight of each evaluation indicator of the energy storage station; and
utilizing, based on the comprehensive weight of each evaluation indicator of each energy storage station, a TOPSIS method to determine an evaluation grade of each energy storage station.

2. The method according to claim 1, wherein the at least one evaluation indicator comprises
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

3. The method according to claim 2, wherein the step of obtaining an indicator score of at least one evaluation indicator of the energy storage station comprises
determining an indicator score of the charge and discharge capacity based on an actual dischargeable power of the energy storage station, a rated power of the energy storage station, an actual dischargeable volume of the energy storage station, and a rated energy of the energy storage station;
determining an indicator score of the energy efficiency level based on an on-grid electricity of the energy storage station, an off-grid electricity of the energy storage station, a total charging amount of the energy storage station, a total discharging amount of the energy storage station, and a self-consumption electricity of the energy storage station;
determining an indicator score of the failure frequency based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station;
determining an indicator score of the power control based on an active-power change rate of the energy storage station and an up/down active-power adjustment speed of the energy storage station;
determining an indicator score of the peak-shaving and valley-filling capability of the system based on a maximum available charging power of the energy storage station, a maximum available discharging power of the energy storage station, a response lag time of the energy storage station, and a steady-state control deviation of the energy storage station;
determining an indicator score of the system frequency regulation based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station;
determining an indicator score of the reactive power support based on an automatic-voltage-control adjustment speed of the energy storage station, an automatic-voltage-control adjustment precision of the energy storage station, and an automatic-voltage-control response time of the energy storage station;
determining an indicator score of the response success rate based on actual execution success times of an automatic-voltage-control and automatic-power-generation-control instructions from a grid within a preset operation scheduling cycle of the energy storage station, and a total number of the automatic-voltage-control and automatic-power-generation-control instructions issued by the grid to the energy storage station;
determining an indicator score of the equivalent utilization coefficient based on a number of operating hours of the energy storage station and a number of statistical hours within an evaluation period of the energy storage station;
determining an indicator score of the outage coefficient based on an unplanned outage coefficient of the energy storage station, a planned outage coefficient of the energy storage station, a number of unplanned outage hours of the energy storage station, a number of planned outage hours of the energy storage station, and the number of the statistical hours within the evaluation period of the energy storage station;
determining an indicator score of the availability coefficient based on an available time of the energy storage station within the evaluation period and the number of the statistical hours within the evaluation period of the determining an indicator score of the frequency proactive support capability based on a steady-state frequency deviation of the energy storage station, a maximum frequency change rate of the energy storage station, a maximum frequency deviation of the energy storage station, an unbalanced power of the energy storage station, an equivalent damping of a system where the energy storage station is located, a primary frequency control intensity of the system where the energy storage station is located, and an equivalent inertia of the system where the energy storage station is located;
determining an indicator score of the voltage proactive support capability based on a matrix of reactive power flowing from regional power grid boundary to internal regions for which the energy storage station participates in regulation, a matrix of voltage at regional power grid boundary nodes for which the energy storage station participates in regulation, and a matrix of parameters at the regional power grid boundary nodes for which the energy storage station participates in regulation;
determining an indicator score of the transient stability support capability based on an additional active output of the energy storage station to the system during transient processes, an additional reactive output of the energy storage station to the system during the transient processes, a frequency deviation at a grid connection point of the energy storage station, and a natural logarithm voltage deviation at the grid connection point of the energy storage station;
determining an indicator score of the cost per unit of electricity based on a total cost of the energy storage station within the evaluation period and the total discharging amount of the energy storage station within the evaluation period;
determining an indicator score of the net present value based on a revenue of the energy storage station within the evaluation period, a cost and a discount rate of the energy storage station within the evaluation period;
determining an indicator score of the return on investment based on an annual-interest pre-tax profit of the energy storage station in a normal year and a total investment of the energy storage station;
determining an indicator score of the carbon emission reduction based on a carbon emission coefficient and a released renewable energy amount of the energy storage station;
determining an indicator score of the effective emission reduction rate based on a clean energy generation amount of the energy storage station within the evaluation period and the total discharging amount of the energy storage station within the evaluation period; and
determining an indicator score of the clean energy absorption rate based on the clean energy generation amount of the energy storage station within the evaluation period and a maximum clean energy generation amount of the energy storage station.

4. The method according to claim 1, wherein the objective weighting method is a CRITIC weighting method.

5. The method according to claim 1, wherein the step of determining a comprehensive weight of each evaluation indicator of the energy storage station based on the objective weight and the subjective weight of each evaluation indicator of the energy storage station comprises
establishing an objective function based on a minimum discrimination information principle for determining the comprehensive weight; and
utilizing the objective function to determine the comprehensive weight of each evaluation indicator of the energy storage station based on the objective weight and the subjective weight of each evaluation indicator of the energy storage station.

6. A device for determining a grade of an energy storage station based on an index evaluation system, wherein the device comprises
an indicator score acquisition module, configured for obtaining, for at least one energy storage station, an indicator score of at least one evaluation indicator of the energy storage station;
an objective weight determination module, configured for utilizing an objective weighting method based on an indicator score of each evaluation indicator of the energy storage station to determine an objective weight of each evaluation indicator of the energy storage station;
a subjective weight determination module, configured for utilizing a DEMATEL-ANP mixed decision-making model based on the indicator score of each evaluation indicator of the energy storage station to determine a subjective weight of each evaluation indicator of the energy storage station;
a comprehensive weight determination module, configured for determining a comprehensive weight of each evaluation indicator of the energy storage station based on the objective weight and the subjective weight of each evaluation indicator of the energy storage station; and
an evaluation grade determination module, configured for utilizing, based on a comprehensive weight of each evaluation indicator of each energy storage station, a TOPSIS method to determine an evaluation grade of each energy storage station.

7. The device according to claim 6, wherein the at least one evaluation indicator comprises
a charge and discharge capacity, an energy efficiency level, a failure frequency, a power control, a peak-shaving and valley-filling capability of a system, a system frequency regulation, a reactive power support, a response success rate, an equivalent utilization coefficient, an outage coefficient, an availability coefficient, a frequency proactive support capability, a voltage proactive support capability, a transient stability support capability, a cost per unit of electricity, a net present value, a return on investment, a carbon emission reduction, an effective emission reduction rate, and a clean energy absorption rate.

8. The device according to claim 7, wherein the indicator score acquisition module is configured for obtaining the indicator score of at least one evaluation indicator of the energy storage station, comprising determining an indicator score of the charge and discharge capacity based on an actual dischargeable power of the energy storage station, a rated power of the energy storage station, an actual dischargeable volume of the energy storage station, and a rated energy of the energy storage station;
determining an indicator score of the energy efficiency level based on an on-grid electricity of the energy storage station, an off-grid electricity of the energy storage station, a total charging amount of the energy storage station, a total discharging amount of the energy storage station, and a self-consumption electricity of the energy storage station;
determining an indicator score of the failure frequency based on a battery-cluster failure frequency threshold of the energy storage station, a process-control-system failure frequency threshold of the energy storage station, a battery-cluster stage-time failure frequency of the energy storage station, and a process-control-system stage-time failure frequency of the energy storage station;
determining an indicator score of the power control based on an active-power change rate of the energy storage station and an up/down active-power adjustment speed of the energy storage station;
determining an indicator score of the peak-shaving and valley-filling capability of the system based on a maximum available charging power of the energy storage station, a maximum available discharging power of the energy storage station, a response lag time of the energy storage station, and a steady-state control deviation of the energy storage station;
determining an indicator score of the system frequency regulation based on a process-control-system protection-action time of frequency adaptability tests of the energy storage station, a process-control-system protection-action frequency of the frequency adaptability tests of the energy storage station, an automatic-power-generation-control adjustment speed of the energy storage station, an automatic-power-generation-control adjustment precision of the energy storage station, and an automatic-power-generation-control response time of the energy storage station;
determining an indicator score of the reactive power support based on an automatic-voltage-control adjustment speed of the energy storage station, an automatic-voltage-control adjustment precision of the energy storage station, and an automatic-voltage-control response time of the energy storage station;
determining an indicator score of the response success rate based on actual execution success times of an automatic-voltage-control and automatic-power-generation-control instructions from a grid within the preset operation scheduling cycle of the energy storage station, and a total number of the automatic-voltage-control and automatic-power-generation-control instructions issued by the grid to the energy storage station;
determining an indicator score of the equivalent utilization coefficient based on a number of operating hours of the energy storage station and a number of statistical hours within an evaluation period of the energy storage station;
determining an indicator score of the outage coefficient based on an unplanned outage coefficient of the energy storage station, a planned outage coefficient of the energy storage station, a number of unplanned outage hours of the energy storage station, a number of planned outage hours of the energy storage station, and the number of the statistical hours within the evaluation period of the energy storage station;
determining an indicator score of the availability coefficient based on an available time of the energy storage station within the evaluation period and the number of the statistical hours within the evaluation period of the determining an indicator score of the frequency proactive support capability based on a steady-state frequency deviation of the energy storage station, a maximum frequency change rate of the energy storage station, a maximum frequency deviation of the energy storage station, an unbalanced power of the energy storage station, an equivalent damping of a system where the energy storage station is located, a primary frequency control intensity of the system where the energy storage station is located, and an equivalent inertia of the system where the energy storage station is located;
determining an indicator score of the voltage proactive support capability based on a matrix of reactive power flowing from regional power grid boundary to internal regions for which the energy storage station participates in regulation, a matrix of voltage at regional power grid boundary nodes for which the energy storage station participates in regulation, and a matrix of parameters at the regional power grid boundary nodes for which the energy storage station participates in regulation;
determining an indicator score of the transient stability support capability based on an additional active output of the energy storage station to the system during transient processes, an additional reactive output of the energy storage station to the system during the transient processes, a frequency deviation at a grid connection point of the energy storage station, and a natural logarithm voltage deviation at the grid connection point of the energy storage station;
determining an indicator score of the cost per unit of electricity based on a total cost of the energy storage station within the evaluation period and the total discharging amount of the energy storage station within the evaluation period;
determining an indicator score of the net present value based on a revenue of the energy storage station within the evaluation period, a cost and a discount rate of the energy storage station within the evaluation period;
determining an indicator score of the return on investment based on an annual-interest pre-tax profit of the energy storage station in a normal year and a total investment of the energy storage station;
determining an indicator score of the carbon emission reduction based on a carbon emission coefficient and a released renewable energy amount of the energy storage station;
determining an indicator score of the effective emission reduction rate based on a clean energy generation amount of the energy storage station within the evaluation period and the total discharging amount of the energy storage station within the evaluation period; and
determining an indicator score of the clean energy absorption rate based on the clean energy generation amount of the energy storage station within the evaluation period and a maximum clean energy generation amount of the energy storage station.

9. The device according to claim 6, wherein the objective weighting method is a CRITIC weighting method.

10. The device according to claim 6, wherein the comprehensive weight determination module is configured for determining the comprehensive weight of each evaluation indicator of the energy storage station based on the objective weight and the subjective weight of each evaluation indicator of the energy storage station, comprising
establishing an objective function based on a minimum discrimination information principle for determining the comprehensive weight; and
utilizing the objective function to determine the comprehensive weight of each evaluation indicator of the energy storage station based on the objective weight and the subjective weight of each evaluation indicator of the energy storage station.
